(19) United States
(12) Patent Application Publication
(10) Pub. No.: US 2023/0147640 A1
(43) Pub. Date: May 11, 2023

(54) DIELECTRIC ELASTOMER MICROFIBER ACTUATORS

(71) Applicant: ELYSIUM ROBOTICS LLC, Cedar Park, TX (US)

(72) Inventor: Rodrigo Alvarez-Icara RIVERA, Cedar Park, TX (US)

(21) Appl. No.: 17/995,353

(22) PCT Filed: Apr. 2, 2021
(86) PCT No.: PCT/US2021/025603

§ 371 Date: Oct. 3, 2022

Related U.S. Application Data
(60) Provisional application No. 63/003,921, filed on Apr. 2, 2020.
(60) Provisional application No. 63/003,922, filed on Apr. 2, 2020.

(51) Int. Cl. B25J 9/10; B25J 9/12

(52) U.S. Cl. CPC B25J 9/1075; B25J 9/12

(57) ABSTRACT

Disclosed herein are methods and systems for making DEMAs by forming a mechanical and electrical connection between a bundle of dielectric elastomer microfibers comprising a direct mechanical connection between the face of each microfiber and a supportive element, and a direct electrical connection between the core of all microfibers and a metallic contact. Also disclosed are dielectric elastomer (DE) microfibers comprised of an inner electrode, a hollow tube, and an outer electrode, wherein the ratio alpha between the outer and inner diameter maximizes the electromechanical performance of such fiber as an actuator.

### CROSS-REFERENCE TO RELATED APPLICATIONS

This application claims the benefit of priority to U.S. Provisional Application No. 63/003,921, filed Apr. 2, 2020, and U.S. Provisional Application No. 63/003,922, filed Apr. 2, 2020, the disclosures of each are incorporated by reference herein in their entirety for all purposes.

### GOVERNMENT RIGHTS

This invention was made, in part, with government support under Contract No. 140D042000040 awarded by the U.S. DOI/DARPA. The government may have certain rights in the invention.

### TECHNICAL FIELD

The present invention is in the field of artificial muscles and actuators. The present invention is also in the field of robotics and prosthetics.

### BACKGROUND

The need for high-performance robotic actuators. Robotic systems will solve critical socio-economic problems as they become more capable, safer, and cost-effective. To solve these problems a new generation of low-cost, high-dexterity collaborative robots, effective exoskeletons, and seamless prosthetics are needed. Most components for these robotic systems—sensors, computation, algorithms or teleoperation, connectivity, and batteries—are sufficiently mature and cost-effective, except for one critical area: Actuators. These applications require robots to perform arbitrary motions that are non-periodic and therefore need an actuator that is strong and fast, sufficiently precise, controllable, and yet small and lightweight. For untethered applications, efficiency is critical for reducing battery size. For safe interaction with humans, the device must be intrinsically compliant and lightweight, and for prosthetics and military robots, the actuators must be quiet. Despite intense efforts, actuators have not seen any considerable innovation and remain limited by the fundamental principles of electromagnetic motors.

Up until now the best actuators available today for robotics are electric motors and hydraulic drives, yet they are complex, heavy, inefficient, unsafe for human interaction, and expensive. Electric motors are terribly inefficient when operating at low speeds because they have low torque density—a problem that worsens with smaller motors. Hydraulic actuators have higher torque density, but the mass of the valves, pumps, and accessories limit system-wide torque density. Highly geared motors and valve-controlled hydraulic actuators suffer from high mechanical impedance (i.e., they have high output friction, stiffness, and large reflected inertia). These characteristics are problematic in general, but even more so for robots designed to interact with humans, where limb lightness and passive back-drivability are desirable for force-mediated interaction and critical for safety. Joint impedance may be reduced by using lightly geared motors, or closed-loop force feedback control, but because of the low torque density, motors are often too heavy to place inside distal joints. Instead, to reduce limb inertia, motors can be placed inside the body of the robot and connected to the distal joints via a transmission, however multi-link articulated cable drives increase design complexity, cost and weight, and Bowden cables (e.g., bicycle cable brakes) suffer from high static friction, wear, and nonlinear behavior. Using fluid actuators in a hydrostatic configuration with either low-friction linear cylinders or reversible rotary fluid pumps is an alternative, but these require closed-loop control to combat leakage and maintain input-output synchronization, and the high-pressure required poses a severe hazard for pinhole leaks. Overall, current actuation technology is the bottleneck for developing safe, capable, and fully autonomous robots and prosthetics. Accordingly, there is a continuing need to improve actuation technologies for robotics and other applications that do not rely on electric motors and hydraulic drives. The disclosed inventions are directed to these and other important needs.

Dielectric Elastomer microfibers are a promising candidate for realizing low-cost high-performance actuators for general robotic and prosthetic applications. Embodied as coaxial capacitors, such actuators leverage the extraordinary electromechanical properties of dielectric elastomer materials to produce useful and scalable motion that is very similar to the performance of natural muscles. Through their ability to produce tension, and by mimicking the hierarchical structure of natural muscle, Dielectric Elastomer microfiber transducers promise to realize true “artificial muscles” for robotic and prosthetic systems.

Dielectric Elastomers (DE) were identified in the early 2000s, as promising materials to make artificial muscles capable of solving the robotics actuation problem, due to their fast response time (<0.1 s), high energy density, large strain capabilities, low-cost, noiseless operation, and long lifetimes. For the past two decades, research has mostly focused on DE actuators that consist of an elastomer film—which acts as an insulator—sandwiched between two compliant electrodes forming a parallel plate capacitor (Comparative FIG. 1a). Actuators based on DE films can achieve actuation strains greater than 100%, but since these materials require high electric fields, and it is difficult to make very thin films, these actuators typically need high driving voltages (500-10,000V) which complicate integration into robotic systems. DE films don't scale well into large actuators because impurities or defects make films susceptible to catastrophic failure (dielectric breakdown), and they are difficult to stack. Although many configurations and applications have been tried, it has not been possible to extract practical motion from DE films, i.e., for making artificial muscles.

DE microfiber actuators (DEMAs) overcome the limitations of film-based DE actuators. The reader is referred to U.S. Pat. No. 7,834,527 for the pioneering patent originally describing DEMAs, the entirety of which is incorporated by reference herein. Instead of using parallel plate capacitors, DEMAs implement a coaxial capacitor design comprising a plurality of fibers (FIG. 1b). These fibers can be scaled down to a few micrometers in diameter and produced at very low cost. Using small diameter fibers DEMAs can operate at low voltages (<600 V) and produce tension that can be used directly to drive robotic joints just like natural muscles pull on bones. Thousands of fibers can be bundled together to increase reliability and produce strong, scalable actuators that can finally realize the full potential of DE materials as artificial muscles.

DEMAs provide a low-cost, high-performance actuator for robotics and enables a completely new generation of robots. Due to the muscle-like performance of these actuators, robots can now be designed to be highly capable and safe to interact with for humans. They will finally be able to leave the factory floor and be used for a wealth of new applications, as envisioned in many science fiction stories. However now fiction becomes reality. Just like the transistor was the building block that enabled the IT revolution, a practical DE microfiber actuator is the building block that enables the robotic revolution, changing civilization as we know it.

A notable feature about Dielectric Elastomer microfiber Actuators (DEMAs) is that many fibers can be bundled together, so that the forces produced by each individual fiber can be added together to produce a very strong actuator. Realizing this requires that an individual fiber be electrically connected so it can be activated and be mechanically connected to transmit its force. Unfortunately forming the electrical and mechanical connections presents physical and material compatibility challenges.

From a mechanical perspective, previous disclosures and embodiments considered that within a bundled DEMA, individual fibers were mechanically attached to each other only at a bundle seal and the bundle seal was then attached to the cap only at the periphery, and the cap then transferred the load to the system of interest. This imposes severe scalability issues for DEMAs having a large number of bundled fibers, and an increasing overall cross-section area. The problem is that the fibers within the central regions of the bundle seal have to transmit the mechanical load transversely to the perimeter of the bundle seal through adjacent fibers. This leads to a progressive accumulation of force toward the edges and creates a large deformation towards the center of the bundle seal. This is like a beam flexure analysis but extended to a 3D elastic surface. An apt analogy would be the deformation that a trampoline experiences when uniformly loaded with snow: the center of the surface deflects considerably as ultimately all the stress is transferred to the perimeter, and there is a shear stress concentration that grows toward the perimeter of the bundle seal.

From an electrical perspective, previous disclosures and embodiments considered that within a bundled DEMA, the cores of individual fibers were electrically interconnected through a common bulk fluidic conductor filling a common cavity. Given the non-uniform deformation due to the mechanical load (described above), this cavity would need to deform accordingly and create a thinner region towards the edges which would in turn result in poorer conductivity. Overall, the mechanical deformations would result in undesired non-uniform electrical conductivity. Accordingly, there is a continuing need to improve DEMA designs and DEMA materials to overcome these technical challenges.

The disclosed inventions are directed to these and other important needs.

### SUMMARY

The present invention provides an electrically conductive adhesive substrate, and other methods to realize the dual function of electrically and mechanically connecting of at least a majority, and preferably at least substantially all, of the microfibers in a DEMA bundle through a single bulk contact medium, thereby resolving the previous challenges and enabling DEMAs with a considerable number of fibers. The implementation of this dual function connection adhesive also resolves material compatibility issues, as the adhesive bonds the DE microfiber material to the cap material in the presence of the conductive core fluidic electrode.

The present invention also provides methods and systems for forming a mechanical and electrical connection between a bundle of dielectric elastomer microfibers comprising a direct mechanical connection between the face of each microfiber and a supportive element, and a direct electrical connection between the core of most, at least substantially all, or all microfibers and a metallic or conductive contact. These connections are established through a bulk material with adhesive properties, which on one surface is bonded to a conductive cap and on the other it bonds to the annular face of each microfiber. In this way it creates a thin film of adhesive between the conductive cap and the fiber edges. The adhesive may additionally establish a bond between the bundle seal and the conductive contact. Simultaneously, this adhesive has electrically conductive properties and creates a conductive path between the conductive contact and the conductive cores of the fibers, also through a thin film.

The present invention also provides methods and systems to electromechanically connect a bundle of a plurality of dielectric elastomeric microfibers, comprising: a direct mechanical connection between the face (cylindrical ring edge) of each of the dielectric elastomeric microfibers and a supportive element (end cap); and a direct electrical connection between the core of all microfibers and a metallic or conductive contact.

The present invention also provides methods and systems to electromechanically connect a bundle of a plurality of dielectric elastomeric microfibers, comprising: a direct mechanical connection between the face (peripheral edge) of multiple dielectric elastomeric microfibers and a supportive element (end cap); and a direct electrical connection between the core of all microfibers and a metallic or conductive contact.

The present invention also provides DE microfibers, comprising a hollow fiber body characterized as having an outer diameter and an inner diameter, an inner compliant electrode deposed within the interior of the hollow fiber body, and an outer compliant electrode deposed exterior to the hollow fiber body, wherein the ratio alpha of the outer diameter to the inner diameter of the hollow fiber body is an important design parameter that is selected to maximize the electromechanical performance of the DE microfiber as an actuator.

The present invention also provides dielectric elastomer (DE) microfibers comprised of an inner electrode, a hollow tube, and an outer electrode, wherein the ratio alpha between the outer and inner diameter of the hollow tube maximizes the electromechanical performance of such fiber as an actuator. Suitable values of the ratio alpha are preferably selected to maximize the mechanical energy output of the microfibers. In some embodiments the ratio alpha is selected to maximize effective work density. In other embodiments the ratio alpha, is selected to maximize effective specific energy. Some embodiments the ratio alpha, is selected to maximize mechanical power density. In some embodiments the ratio alpha, is selected to maximize mechanical specific power. Other embodiments the ratio alpha is selected to maximize effective strain. In other embodiments the ratio alpha, is selected to maximize effective_stress. In some embodiments the ratio alpha has a value between about 1.1 and 3.

The present invention, in certain preferred embodiments also provides DE microfibers, comprising: a hollow fiber body characterized as having an outer diameter and an inner diameter, an inner compliant electrode deposed within the interior of the hollow fiber body, and an outer compliant electrode deposed exterior to the hollow fiber body, where the ratio, alpha, between the outer diameter and the inner diameter of the hollow fiber body is chosen to maximize the electromechanical performance of the DE microfiber as an actuator.

The present invention also provides dielectric elastomer (DE) microfibers comprised of an inner electrode, a hollow tube, and an outer electrode, wherein the electrical RC time-constant required to charge the DE fiber is lower than about 1000 milliseconds (ms), preferably lower than about 500 ms, and more preferably lower than about 200 ms. In some embodiments the OD is reduced to implement a higher resistivity core that isolates a dielectric breakdown and results in a failure rate of less than 1 in 1000 fibers within a bundle at the target operating voltage. In some embodiments the resistivity of the core is engineered so that the fiber has an electrical time constant below 200. In other embodiments the scale (OD), ratio alpha and resistivity of the core is engineered so that the fiber has an electrical time constant that matches the mechanical time constant of the target system but is not lower.

The present invention also provides dielectric elastomer (DE) microfibers comprised of an inner electrode, a hollow tube, and an outer electrode, wherein the hollow fiber body of the DE microfibers can be comprised of one or more of the following elastomeric materials: silicones, thermosets, thermoplastics; urethanes; polyesters; acrylics and (meth)acrylics.

The present invention also provides dielectric elastomer (DE) microfibers comprised of an inner electrode, a hollow tube, and an outer electrode, wherein the hollow fiber body of the DE microfibers is made from a material characterized as having a Young's Modulus in the range of between about 100 kPa to about 5,000 kPa, preferably between about 300 kPa to about 2400 kPa, or between about 400 kPa and about 2000 kPa, more preferably between about 500 kPa and 1500 kPa, and even more preferably between about 600 kPa and 1200 kPa.

The general description and the following detailed description are exemplary and explanatory only and are not restrictive of the invention, as defined in the appended claims. Other aspects of the present invention will be apparent to those skilled in the art in view of the detailed description of the invention as provided herein.

### BRIEF DESCRIPTION OF THE DRAWINGS

The summary, as well as the following detailed description, is further understood when read in conjunction with the appended drawings. For the purpose of illustrating the invention, there are shown in the drawings exemplary embodiments of the invention; however, the invention is not limited to the specific methods, compositions, and devices disclosed. In addition, the drawings are not necessarily drawn to scale. In the drawings:

FIG. 1 illustrates the operating principles of a (a) Film-based DE actuator vs. a (b) Fiber-based DE actuator;

FIG. 2a illustrates an embodiment of a DEMA according to the present invention; FIG. 2b illustrates an embodiment of a partially exploded view of a DEMA according to the present invention; FIG. 2c illustrates an embodiment of a cross sectional view of a DEMA according to the present invention;

FIG. 3 depicts a photo of several embodiments of DEMAs according to the present invention;

FIG. 4 illustrates Fiber Geometry Characteristics of Dielectric Elastomer Fiber Actuators, labeling the key features and design dimensions;

FIG. 5 illustrates the strain-strain operational characteristics of a variety of DEMAs made according to the present invention, providing the following data curves: a) Simulated Stress vs. Strain and Activation Voltage (V) for a DEMA made from a silicone elastomer compound and designed to maximize its maximum effective work density, (gray shaded area). b) Illustration of the effect on alpha on the strain vs. stress operational space of a DEMAs fiber. c) Effective work density (Stress across strain per unit of volume) that a DEMA can produce as a function of alpha (alpha=fiber OD/ID) showing a sweet spot around alpha=1.9. d) Data from a DEMA fabricated with a commercially-available silicone elastomeric material demonstrating the electromechanical response (stress as function of strain and activation voltage);

FIG. 6 illustrates how the material parameters alpha and Young's Modulus of the hollow cylinders can be varied to control actuator performance;

FIGS. 7a and 7b provides a series of microimages of cross sections from two different DE microfibers, Sample A and Sample B, respectively; FIGS. 7c and 7d, provide plots of the image analysis results for Sample A and Sample B, respectively, of the cross sectional microimages for measuring the outer diameter, OD, and the inner diameter, ID, of the DE fibers;

FIG. 8 is a data plot that compares Strain (%) versus Activation Voltage (V) for DEMAs fabricated from different sized DE microfibers, characterized as alpha=2.05 (squares) and alpha=2.55 (triangles); and

FIG. 9a illustrates a perspective cross sectional view of an embodiment of a DEMA made according to the present invention, and FIG. 9b illustrates a perspective sectional view of an embodiment of a DEMA made according to the present invention.

### DETAILED DESCRIPTION OF ILLUSTRATIVE EMBODIMENTS

The present invention may be understood more readily by reference to the following detailed description taken in connection with the accompanying figures and examples, which form a part of this disclosure. It is to be understood that this invention is not limited to the specific devices, methods, applications, conditions or parameters described and/or shown herein, and that the terminology used herein is for the purpose of describing particular embodiments by way of example only and is not intended to be limiting of the claimed invention. Also, as used in the specification including the appended claims, the singular forms “a,” “an,” and “the” include the plural, and reference to a particular numerical value includes at least that particular value, unless the context clearly dictates otherwise. The term “plurality”, as used herein, means more than one. When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

It is to be appreciated that certain features of the invention which are, for clarity, described herein in the context of separate embodiments, may also be provided in combination in a single embodiment. Conversely, various features of the invention that are, for brevity, described in the context of a single embodiment, may also be provided separately or in any subcombination. Further, reference to values stated in ranges include each and every value within that range.

### Terms

As used herein, the term “fiber” and “microfiber” are used interchangeably.

As used herein, the term “DEMA”, “fiber”, and “microfiber” are used interchangeably.

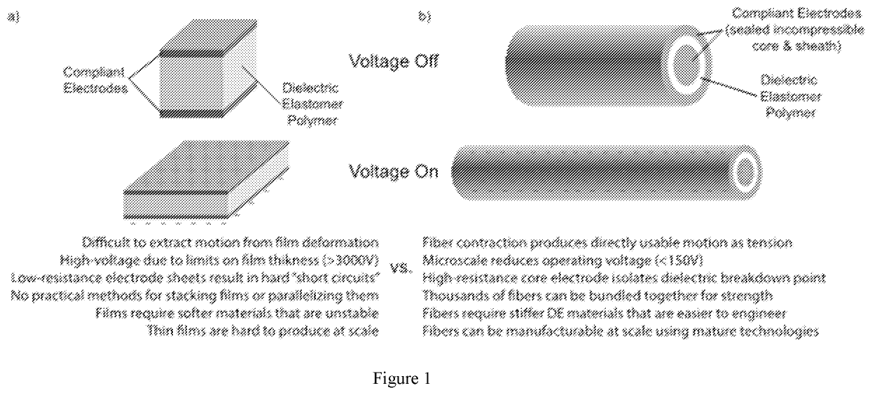

FIG. 1 illustrates the operating principles of a prior art (a) Film-based DE actuator and a (b) Fiber-based DE actuator. a) Illustration of film-based DE actuator's mode of operation. An elastic insulator film is sandwiched between two compliant electrodes. The insulator is typically pre-strained using a frame. When a voltage is applied, the electrodes are charged, and Coulomb's forces squeeze the insulator causing it to flatten and the film to elongate in two dimensions. b) Illustration of a fiber-based DE actuator's mode of operation. An elastic insulator hollow fiber is filled with a fluidic electrode (positive) and surrounded by a negative electrode. When a voltage is applied, the electrodes are charged, and Coulomb's forces squish the fiber radially, causing it to grow in length. When the voltage is removed, the elastic nature of the elastomers produces tension in film- and fiber-based DE actuators that can move external loads. In another embodiment the inner fluidic electrode can be negative, and the microfiber can be surrounded by a positive electrode. Fluidic electrodes provide and advantage because they do not present an elastic force, yet other compliant electrodes may be used. In another embodiment, the inner compliant electrode may only be applied to the inner surface.

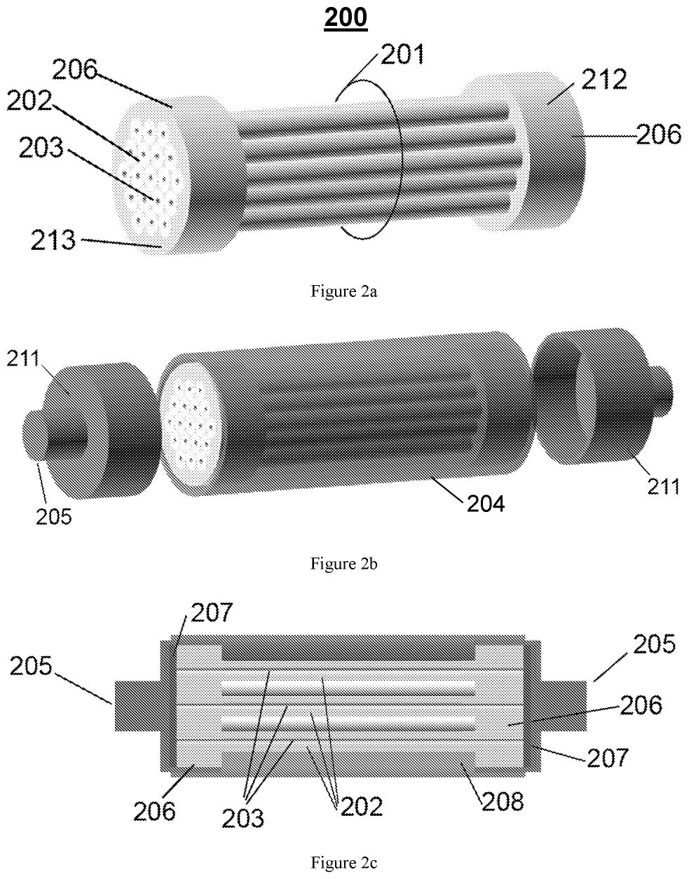

Referring to FIG. 2a, a DEMA 200 comprises a fiber array 201, which comprises a plurality of DE microfibers 202, made by forming bundle seals 206 from a filler or potting material at each distal end, which filler material may be the same material for making the DE microfibers 202 or different, that isolates the inner fiber cores 203 of the DE microfibers from their outer surfaces. Each bundle seal 206 is shown having a periphery 212 and a face 213. A face 213 of the bundle seal 206 refers to a distal end of the fibers 202 and the fiber cores 203. The bundle seals are the part of the bundle that adheres all of the fibers together and separates the ends (cores) from the sheaths (or middle section).

Referring to FIG. 2b, the DEMA 200 is shown with an encapsulating sleeve 204 surrounding the fiber array 201 and the bundle seals 203. Two insulating caps 211 (shown removed to illustrate the fiber array within) are provided at distal ends of the DEMA, each having an electromechanical contact 205. Insulating caps 211 can be made of an electrically insulating material that covers and electrically insulates the electromechanical contact 205.

FIG. 2c provides a longitudinal cross sectional view of DEMA 200, which illustrates the plurality of DE microfibers 202 in cross section to reveal the fiber cores 203 which are filled with a compliant conductive electrode material to be in electrical communication with an electrically conductive adhesive 207 provided at each distal end to mechanically bond and electrically connect the plurality of DE microfibers 202 and the bundle seals 206 to the electromechanical contacts 205 at each end. The electrically conductive adhesive 207 adheres the faces of the distal ends of the DE fibers 202 mechanically to the electromechanical contact 205 and electrically connects the interior of the fiber cores 203. Also shown is a compliant ground electrode 208 made from a compliant conductive material or medium, such as a conductive fluid, which surrounds the exterior of each of the DE microfibers 202. The DE microfibers 202 comprise an elastomeric material which forms the cylindrical walls of the hollow (when unfilled) microfibers and, accordingly, the distal end faces of the microfibers which are sealed to the electromechanical contacts 205 via the electrically conductive adhesive 207. Electromechanical contacts 205 typically are a portion of the insulating cap 211 that are electrically conductive and serves as a mechanical and electrical connector between the bundled fibers and the system in which it is installed for actuation, such as a robotic system.

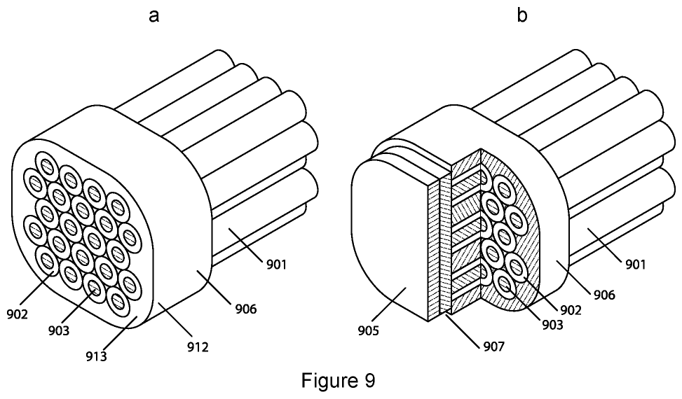

An embodiment of a design of the electromechanical connection of the microfiber bundle with the bundle seal according to an embodiment of the present invention is further illustrated in FIGS. 9a and 9b. FIG. 9a illustrates a perspective cross sectional view of an embodiment of a portion of a DEMA made according to the present invention. Fiber array 901 is shown encapsulated by bundle seal 906, which comprises a periphery 912 forming a side wall for the seal. The face 913 of the bundle seal is also shown positioned flush with the distal ends of fibers within the fiber array, the distal ends being depicted as the face of the fiber end 902 surround the fiber core 903. During operation, fiber core 903 is filled with a compliant electrode material, such as a suitable electrically conductive fluid, and the fiber array 901 also has a suitable compliant electrode material positioned directly adjacent to the exterior of each of the fibers with the array 901. FIG. 9b illustrates a perspective sectional view of an embodiment of a DEMA made according to the present invention. FIG. 9b illustrates a perspective sectional view of an embodiment of a portion of a DEMA made according to the present invention. The DEMA is like the one in FIG. 9a, but also includes a layer of an electrically conductive adhesive 907 to electromechanically bond an electromechanical contact 905 to the face of the bundle seal, as well as to the face of the distal fiber ends and to maintain electrical conductivity with the compliant electrode material within the fiber core.

Suitable mechanical and electrical connections can be achieved by using an electrically conductive adhesive or compound. For example, the adhesive can be a conductive adhesive that can directly bond to the microfiber material in the presence of the fluidic electrode. The adhesive can also bond to the microfiber core electrode in embodiments where the core electrode is non-fluidic. The adhesive must have the proper curing properties or chemical reactions to establish the bond when in the presence of the fiber material, the conductive core electrode and the conductive cap. Suitable adhesives include epoxies, silicones and cyanoacrylates with proper dopants or fillers to be made electrically conductive. The electrical connection can be achieved by forming a fluidic cavity between the core of the microfibers and a conductive contact, wherein the mechanical connection can be achieved at the periphery of the bundle's seal. A conductive support having an array of pins or contacts that aligns with the cores of the microfiber bundle and where the pins are inserted into the cores. In some embodiments the mechanical connection is strengthened by an adhesive.

In certain embodiments the electrical connection can achieved by a bonding pad ring and bonding wires similar to an integrated circuit.

In certain embodiments the mechanical connection is achieved by an adhesive on the face or periphery of the bundle seal.

In one embodiment, a specialized adhesive or bonding material that is electrically conductive is applied to a metallic or conductive contact shaped to cover the entire open face of the bundle seal and this is then bonded to the open face of the bundle seal. In this way the adhesive or bonding material creates an intermediate layer between the metallic or conductive contact and the fiber's core, the fiber's body and the bundle seal material. Through this method, the metallic or conductive contact is electrically connected (through the conductive adhesive or bonding material) to the cores of all microfibers and allow for electrical charge to be transmitted into and out of all fibers cores. Through this method, the bodies of all fibers and the bundle seal material are mechanically connected to the metallic contact and allow for force (and or stress or tension) to be transmitted between each fiber and the metallic contact to produce motion on an external load.

Electrically conductive adhesives or bonding material are preferably selected to have the following unique properties:

1. It is electrically conductive with a volume resistivity less than about 400 ohm cm.

2. It can bond to the fiber material, e.g., a silicone elastomeric material, directly or via the use of primers and pre-treatments, to give rise to a tensile bond strength greater than about 100 kPa.

3. It can cure in the presence of fluidic electrodes, where such electrodes may be made of water, conductive grease, ionic fluids or other.

In another embodiment, instead of using a bulk metallic contact, the connection is made through a silicone interposer integrated circuit or a fine-pitched PCB that has patterned connectivity so that subsets of fibers are connected to a part of the pattern and may be isolated from other subsets. In this embodiment the adhesive or bonding material has the additional property of having much higher axial than lateral conductivity, or alternatively this adhesive can be patterned in a way that isolates fiber subsets from each other.

In another embodiment, instead of using an adhesive or bonding material this volume is comprised of a fluidic cavity, filled with the same electrode as the fibers, such that the fiber cores are directly connected electrically to the metallic or conductive contact. In this embodiment the mechanical connection is made at the perimeter (not the face) of the bundle seal, or via a suitable flat ring contact near the edge defined by the face and perimeter. The mechanical connection may be achieved with an adhesive, via a direct casting of the bundle seal material, via some other thermal or chemical method, or via a mechanical clip or joint.

In another embodiment, the metallic or conductive contact has a series of pins (or needles) that align with fibers and are inserted into the cores to establish an electrical connection. In this embodiment, the mechanical connection can be made by simple friction of the pins into the fibers, via an adhesive on the face of the bundle seal, via an connection on the perimeter of the bundle seal or any combination of the above.

In another embodiment, the metallic connection is shaped such that it has a set of electrical contacts around the bundle seal face (6) to which bonding wires can be attached and such bonding wires connected to the fiber cores (2). This embodiment is similar to a standard IC package with peripheral pads. In this embodiment the mechanical connection can be made by any of the previously described methods.

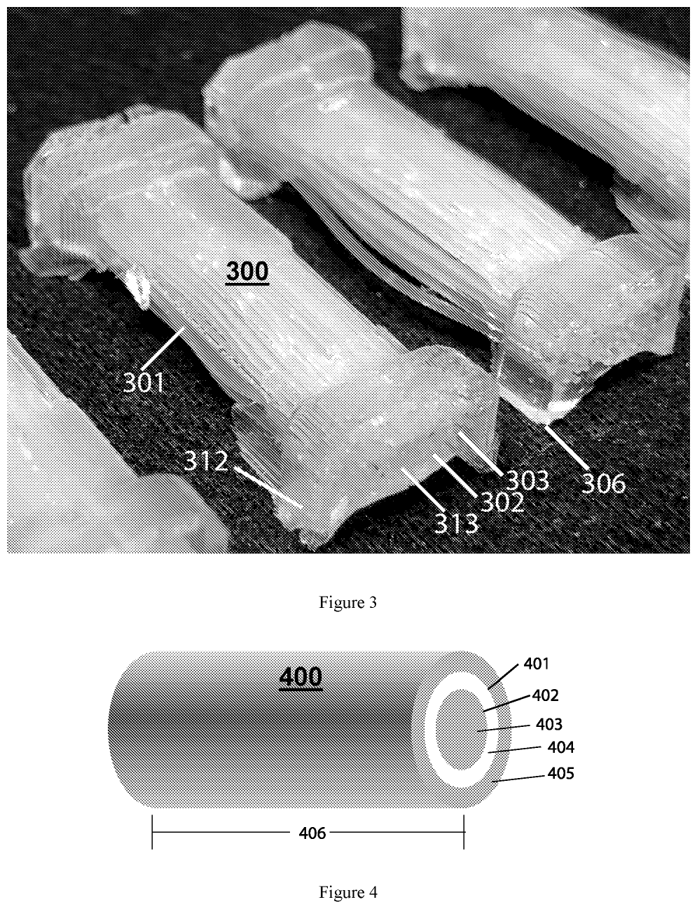

DEMAs were prepared as described further below in the examples section. FIG. 3 provides a photo of several “Dry” DEMAs made prior to adding the conducting fluid to surround the fibers, or within the cores, and without the electrically conductive adhesive. “Dry” DEMA 300 is shown to include fiber array 301, the distal ends of which are encapsulated with a bundle seal 306. The bundle seal 306 holds the ends of the fibers 302 together to present each of the open fiber cores 303 at the face 313 of the bundle seal.

Engineering DEMAs as high-performance actuators. Dielectric Elastomer microfiber actuators (DEMAs) can be engineered to provide the correct balance of mechanical and electrical properties to solve the need of general robotic systems. Through the selection of specific dielectric elastomer (DE) materials (or blends) and by controlling the geometry and scale of a DEMA, we can design the actuators' energy density, effective strain, blocking and effective_stress, stiffness, efficiency, response time and many other critical properties to suit robotic applications. Herein are described DEMAs designed to maximize actuation performance along several of its critical dimensions.

As described herein we will use scale invariant measures of displacement and force. Therefore, instead of describing the length and actuation displacement requirements of a given DEMA, we use the relative elongation of a DEMAs described as strain which is computed as strain=(length/initial_length)−1. Instead of describing the force a DEMA can produce we consider the stress which is defined as stress=force/cross_section_area. The cross_section_area=Pi*(OD/2)∧2. In this way the force produced by a DEMA actuator comprised of a plurality can be computed by the sum of all the cross-section areas from all fibers multiplied by the intrinsic stress. Through these scale invariant metrics, we can quantify the intrinsic performance of individual fibers as well as large scale integrated actuators. We can also describe the intrinsic optimization methods which for individual fibers directly translate into macro-scale optimization of integrated actuators.

The electromechanical performance of a DEMA is determined by a combination of the electromechanical properties of its materials and its geometry.

From a material perspective, the key material properties that characterizes the microfiber body are: its elasticity modulus (Young's modulus), its Dielectric Constant and its breakdown voltage; and for the electrode material the key property is its volume conductivity. We have discovered a sweet spot regarding the elasticity modulus for DEMA materials, where materials having a modulus between about 600 kPA and about 1200 kPa. Regarding other properties, the material should have the highest possible dielectric constant and the highest possible dielectric breakdown voltage so that it is able to hold as much electrical charge as possible. Some other desired properties are low viscous losses, low dielectric losses, low hysteresis, low temperature dependencies, no creep, and high reliability.

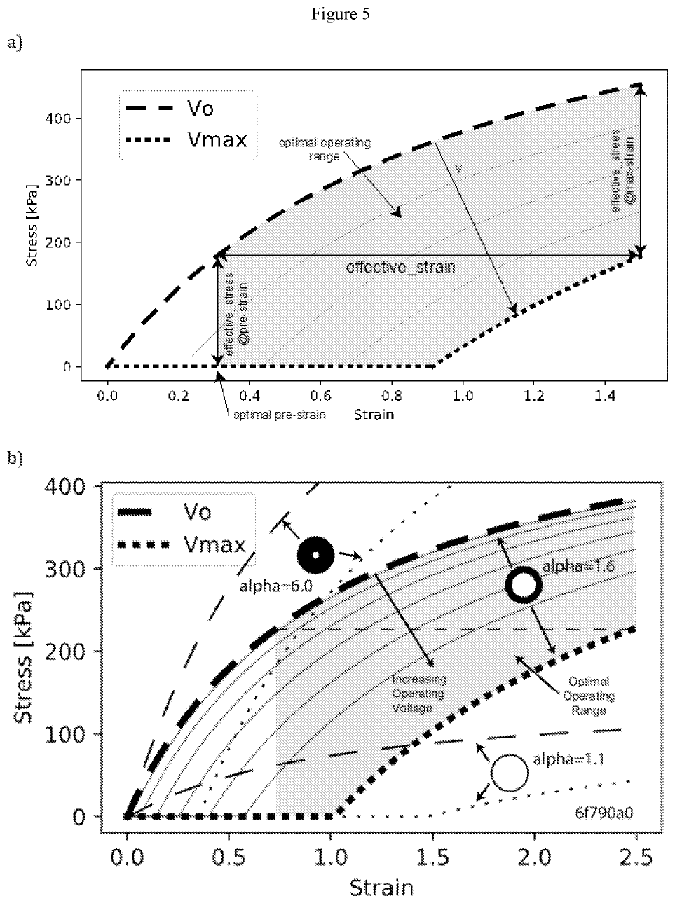

Regarding a DEMA's geometry, for any given material the fiber's dimensions play a fundamental role in determining their performance. Referring to FIG. 4, DEMA 400 can be characterized by its fiber body outside (outer) diameter 401 (OD), its fiber body inner diameter 402 (ID), the ratio of the outer diameter 401 to the inner diameter 402, alpha=OD/ID, and its length 406 (L). Surprisingly, we have discovered that, for a given DE material, the alpha ratio is an important scale invariant design parameter for controlling the performance metrics of a DEMA and can be selected to maximize its particular mechanical capabilities. We have surprisingly discovered that the choice of alpha, for DEMAs made from a specific DE material, determines maximum energy density, effective strain, blocking stress, stiffness and efficiency, and the optimal alpha is slightly different for different DE materials. Once alpha is chosen, the general scale of the fiber, defined by its outer diameter of the fiber will determine its operating voltage, and reliability.

By carefully engineering the correct alpha value, we can produce DEMAs designed to generate the most mechanical work (force*displacement, or stress*strain) per unit of mass also known as the specific energy, or alternatively, the most mechanical work per unit volume, also known as the energy density. Both of these are fundamental actuator performance metrics for robotic systems. Additionally, alpha can be engineered to control other metrics as appropriate.

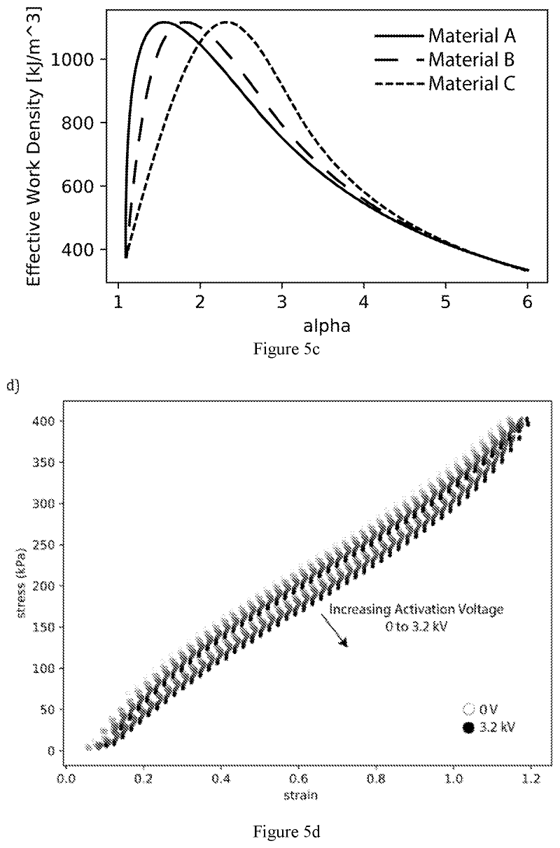

FIG. 5a shows the expected electromechanical behavior of a simulated DEMA, and FIG. 5d shows the measured results of an early prototype. The protocol for generating these figures is as follows: A single DEMA is mounted on an electromechanical tester for characterization (FIG. 5d) or the simulated system is computed (FIG. 5a). The electromechanical tester stretches a DEMA, and then returns to its initial length, while recording the resulting tensional force. The electomechanical tester repeats stretching and relaxation cycles, while applying a different activation voltage through each cycle to characterize the electromechanical behavior of the DEMA. This characterization results in the force of a DEMA being measured vs. its length and activation voltage. FIG. 5a shows the DEMA response to zero activation voltage (Vo) and to maximum activation voltage (Vmax). FIG. 5d shows the DEMA response to several activation voltages ranging from zero (Vo) to maximum activation voltage (progressively darker circles). For scale invariance, the length is converted into strain (where strain=length/initial_length−1) and the force is converted into stress (where stress=force/initial_cross-section_area).

The mechanical work that a DEMA can produce can be calculated by analyzing the data from FIGS. 5a and 5d. The maximum mechanical work a DEMA can produce is determined by an area of operation within the curves of zero activation voltage and maximum activation voltage. There are several ways that this area can be defined, all of which are considered for this invention. As means of example, FIG. 5a illustrates one method where an effective_stress value is selected as a target parameter for defining the operating region. This effective_stress defines the guaranteed stress (or the force) that the actuator will be able to produce through its target operation. Based on the effective_stress, the minimum pre-strain value necessary to produce this stress when zero-activation is selected. The maximum strain value is selected as the strain value at which the DEMA can produce the effective_stress under maximal voltage activation. From this definition, the maximum mechanical work that the DEMA can produce is the area defined between the minimal and maximal stress and between the minimal and maximal strains.

FIG. 5b illustrates the electromechanical behavior of simulated DEMAs with different alpha ratios. As can be seen, for low alpha ratios, the stress-strain response of a DEMA becomes very shallow, since the cross-section of the DEMA has very little elastomer. Alternatively, for high alpha values, the stress-strain response becomes very steep since the cross section are has a lot of elastomer. FIG. 5b shows how for low and high values of alpha, the operating region (for any effective_stress) becomes very narrow, and as such the mechanical work that the DEMA can produce is diminished. However, there is a sweet spot, at which the operation region is maximal.

After computing (or measuring) the mechanical work that a given actuator can produce, to facilitate comparison between DEMAs made from different materials, it is useful to divide the actuator's mechanical work by its volume (to get the work density) or by its mass (to get its specific energy). FIG. 5c shows how for a given material, the work density varies with alpha, and how there is an optimal alpha value that maximizes the DEMA's performance. Moreover, FIG. 5c shows how there is a narrow peak around values of alpha=2 and a steep decline from those. As such, the process of identification and selection of alpha to within this range is a fundamental component of this invention.

By carefully choosing the alpha value for a particular material we can engineer DEMAs that operate at their performance sweet spot. For example, FIG. 5c shows how the Effective Work Density of a DEMA is affected by the alpha ratio chosen. Accordingly, suitable DEMAs have alpha values between about 1.2 and about 4, preferably between about 1.3 and about 3, even more preferably between about 1.5 and about 2.5, even more preferably between about 1.7 and about 2.2, and most preferably between about 1.8 and 2.1.

and by carefully choosing the OD we can engineer fibers that have the lowest possible operating voltage yet have the correct reaction time for their application. Finally, a primary parameter affected by the length (6) of the fiber is the electric RC time constant of the fiber which also depends on the scale of OD (1).

FIGS. 5a-b show the operating space of a DEMA as simulated from first principles. Referring to FIG. 5a, the dashed line (Vo) describes the passive behavior of a DEMA as it is strained from 0 to 140%. As the DEMA is stretched, due to the elastic nature of the fiber's material (4) the fiber produces stress like an elastic element. When a voltage is applied between the core (3) and the outer surface of the fiber (5), the charges accumulated on the coaxial capacitor formed by the fiber (3,4,5) create an electrostatic stress (or Maxwell stress) that squeezes the fiber radially and cause it to reduce the tension. The black lines parallel to the Vo line illustrate this. The dotted line Vmax illustrates the stress vs. strain behavior of a fiber at the maximum possible operating voltage (with a safety factor) before the material reaches dielectric breakdown. Overall, by applying a specific voltage to a DEMA at any given strain, the designer of a robotic system can command the DEMA to produce any stress within its operating range. It is worth noting that for the DEMA to produce any initial stress, it must be pre-strained, and that there is a region within which the DEMA can be activated to produce zero stress. The robotic designer will learn to leverage the operation space to suit her application.

When engineering DEMAs for a specific application, reducing the OD (1) reduces the operating voltage and as such is a very desired optimization. For a given alpha value, reducing OD (1) also increases the reliability of a bundle of fibers because each fiber will exhibit better self-isolation properties (described below). Without being limited by any theory of operation, the compromise of reducing the OD for a fiber of any given length is that this will increase the core resistance and therefore the electrical RC time constant. Accordingly, there is a limit to how much the OD should be reduced for a given application. A given actuator whose fibers are of known length will have an electrical RC time constant defined by the length of the fiber, the value of alpha and its OD. Therefore, once the necessary length for an actuator is set, the scale of the fiber, as generally governed by its OD, can be set to ensure that the DEMA's electrical time constant is faster than the application requires.

FIG. 5b shows how a DEMA's operating space is affected by the choice of alpha. For any given DE material, low values of alpha (e.g., about 1.1) result in microfibers with very thin walls, which due to the small amount of elastomeric material have a very low effective elasticity modulus and generally cannot produce appreciable stress when actuated or strained. In contrast, DEMAs with very high values of alpha (e.g., about 6) result in microfibers with very thick walls, which due to the large amount of elastomeric materials have a high effective elasticity modulus. Although, thick-walled microfibers can produce considerable stress they are too stiff and therefore their electroactive response is diminished, having a smaller operating space and ultimately being able to produce less mechanical energy output. For the material illustrated in FIG. 5b, the optimal value of alpha is about 1.6 which balances the stiffness of the elastomer material to maximize the operating space and produce the greatest mechanical energy output.

Regarding reliability, DEMAs have a peculiar advantage over film-based Dielectric Elastomer Actuators. This advantage comes from the fact that in a DEMA with a pre-defined alpha value, reducing the OD, and therefore the ID, to a small value (e.g., less than about 200 μm), results in an increase in resistance of the inner electrode because the area of this conductor is reduced. This increase in resistance is advantageous because when a failure due to dielectric breakdown happens along the fiber length, this point of failure, or short circuit, is naturally isolated from other fibers and from the power supply via a the high-resistance of the core. In a sense, the high-resistance of a small DEMAs core, creates a soft short-circuit that to a considerable extent isolates a failure point from the rest of the individual fiber and from the other fibers bundled in a DEMA. Since increasing the resistance of a DEMA core affects the electrical RC time constant but does not affect the electrical efficiency, it is desirable to increase the core resistance to the maximum value possible that satisfies the electrical time constant of the application. The resistance of the inner (core) electrode can be controlled by the selecting the scale (OD) of the DEMA as well as by selecting an electrode material with the desired volumetric resistivity.

Suitable electrode materials can be characterized as compliant, fluidic or both. Fluidic materials will typically take the shape of their container or adhere to a surface as a thin film when permitted by significant surface tension forces. Various examples of suitable electrode materials are also provided in U.S. Pat. No. 7,834,527, the relevant portion of which pertaining to compliant electrodes is incorporated by reference herein. Suitable electrode materials for use in the inner (core) of a DE microfiber are typically fluidic. Suitable electrode materials may be aqueous or non-aqueous in nature. Aqueous fluidic electrode materials include water having dissolved ions and/or electrolytes to give rise to a volumetric resistivity in the range of from about 5 to 5000 ohm-cm. Suitable non-aqueous conductive fluids are also envisioned, such as conductive greases, which typically are composed of a concentrated dispersion of electrically conductive particles, such as metal flake, carbon black, graphene, carbon nanotubes and the like, in a viscous fluid matrix. An example of a commercially available conductive grease is Nyogel™ 756G, Nye Lubricants, Fairhaven, MA, which is reported to have a volumetric resistivity of 30 ohm-cm (0.3 ohm-m). Suitable conductive fluids may also include conductive inks.

For illustrative purposes we can describe DEMAs made from a commercially available DOW Corning Sylgard™ silicone elastomer compound. For DEMAs fabricated with such a material, we have experimentally observed that fibers with an OD=˜133 μm and alpha ˜2 have a maximum operating voltage of 864 kV at which they can produce a strain of 4.9%. FIG. 5d shows data recorded from such a DEMA. Simulations project that reducing the outer diameter to 50 μm will reduce the operating voltage to ˜300 V. The effective strain, effective_stress, mechanical energy output per unit volume or mass does not change with this scaling.

Examples of commercially-available elastomeric materials and precursors for making the elastomeric materials that are suitable for making the hollow fibers used in the present invention include the Sylgard™ family or the Silastic LC family available from Dow Chemical, the DMS-V31 series from Gelest, thermoplastic elastomers such as Septon2063 from Kuraray, the Elastosil Series of liquified rubber compounds from Wacker Chemie, the Silopren UV Electro series from Momentive, the acrylic polymers used by 3M for their 4905 VHB tape series, the TC-5000 series from BJB Enterprises, and the CF19 series from Nusil.

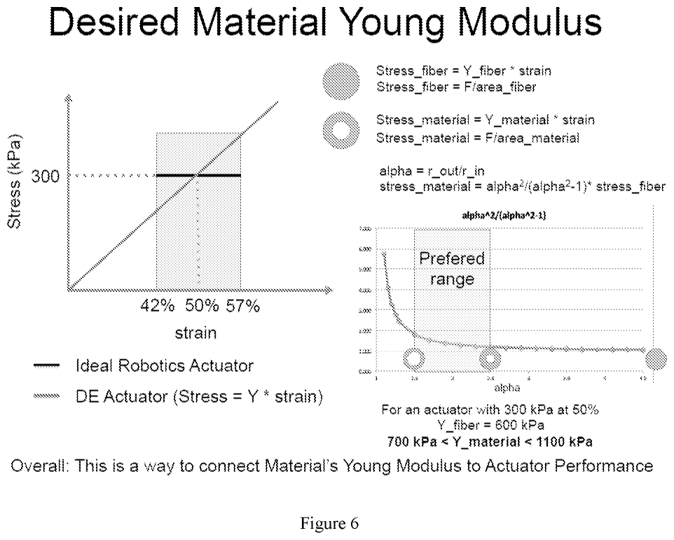

To achieve preferred embodiments for a given length and displacement requirement the design of DEMAs involves three considerations: the material selection, the selection of an OD and the selection of an alpha value. In some preferred embodiments, the hollow fiber materials comprise elastomeric materials characterized as having a suitable Young's modulus to provide tension to the actuator, a high dielectric constant and a high dielectric breakdown. Suitable values of the Young's Modulus of suitable hollow fibers can be in the range of from about 100 kPa to about 5,000 kPa, preferably between about 300 kPa to about 2400 kPa, between about 400 kPa and about 2000 kPa, more preferably between about 500 kPa and 1500 kPa, and even more preferably between about 600 kPa and 1200 kPa. This is further illustrated in FIG. 6. The preferred OD is the minimal OD that still results in a fiber having an electrical RC time constant smaller than the required mechanical response time. The alpha value can then define a “sweet spot” in electromechanical performance, wherein performance can be maximized by adjusting the effective work density or effective specific energy, effective_stress, effective_stress or electromechanical efficiency.

For robotic systems that are intended to operate at scales similar to humans or animals, a time constant of 100 to 200 milliseconds (ms) is appropriate. In some applications a time constant as low as 50 ms can be used, so a range of 50 to 200 ms is also useful. Specialized microscale actuators are also envisioned to require time constants even smaller than 50 ms, perhaps as low as 40 ms, or 30 ms, or 20 ms, or 10 ms, to provide a fast twitch response or for operation in microrobots. In other embodiments the time constant can range from 75 ms to 150 ms. Other structural applications that are much larger in scale may require much slower time constants (e.g., greater than about 1000 ms, or even up to about 10,000 ms) such as the closing of doors or movement of walls and partitions, while other specialized motion applications such as optical deflectors or sound speakers may require time constants smaller (i.e., faster) than 10 ms, perhaps as small as 1 ms, or even 0.1 ms.

As used herein, the term “fluidic” in reference to conductive materials refers to materials capable of flow, for example, for flowing into the inner core of the hollow fiber body of a DE microfiber. In some embodiments it is envisioned that the fluidic conductive materials act as a liquid which essentially completely fills the inner core of the hollow fiber body. In these embodiments the fluidic conductor in the inner core is essentially incompressible at operating conditions. In other embodiments it is envisioned that fluidic conductor forms a liquid film on the interior wall of the inner core of the hollow fiber body, with another type of matter, such as a compressible solid, like a foam or powder, or a compressible fluid like a gas such as air, nitrogen or argon, to fills the remainder of the inner core. In such embodiments one can characterize the inner core as being compliant, e.g., compressible and/or at least partially deformable under operating conditions. A key consideration of the inner fluidic electrode is that its volume remains virtually constant during the microfiber elongation, and in doing so it constrains the microfiber deformation so that as its walls are compressed by Maxwell stress, the fiber must grow in length and shrink in diameter to maintain this constant volume.

### EXAMPLES

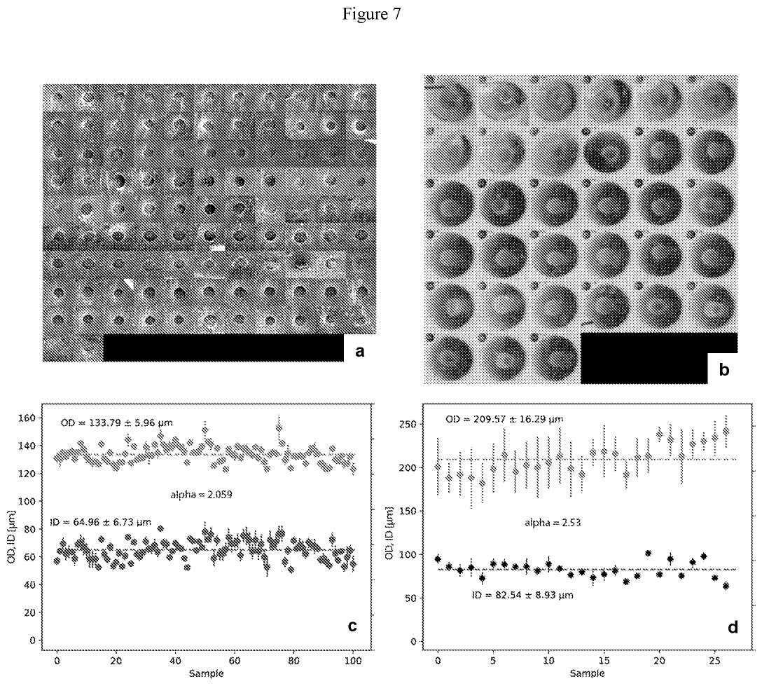

DEMAs were fabricated from DE fibers synthesized using commercially available silicone resins from DOW Corning using a process similar to that described in U.S. Pat. No. 7,834,527B2. For the purpose of this disclosure, two sets of fiber samples were cross-sectioned and imaged through a calibrated inspection microscope and their outer an inner diameter were measured using image analysis as shown in FIG. 7 and summarized in Table 1. FIGS. 7a and 7b shows a series of microimages of cross sections from two different DE fibers, Sample A and Sample B, respectively. FIGS. 7c and 7d, for DE fibers Sample A and Sample B, respectively, provides the image analysis results that was obtained for each of the cross sectional microimages for measuring the outer diameter, OD, and the inner diameter, ID, of the DE fibers. Table 1 summarizes the mean outer and inner diameters and the alpha ratio for Samples A and B, as well as the ratio of outer diameter, OD, from sample A to B at 1.57.

TABLE 1

| | Sample A | Sample B | Ratio |
|---|---|---|---|
| Outer Diameter [μm] | 133.79 | 209.57 | 1.57 |
| Inner Diameter [μm] | 64.96 | 82.54 | 1.27 |
| Alpha | 2.060 | 2.539 | NA |
| Stress [kPa] | 7.41 | 10.92 | 1.47 |

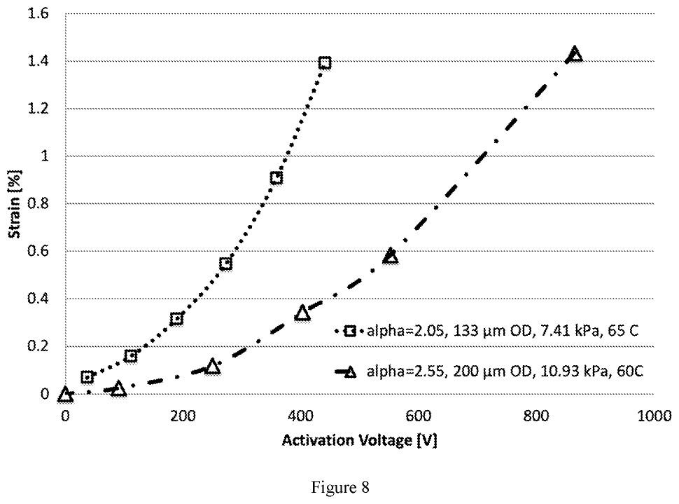

The DEMAs pictured in cross-section FIG. 7 were electromechanically tested through an isotonic test in which a fixed mass is hung from a DEMA segment and then it is electrically activated with a 1 Hz sinusoidal voltage at different amplitudes. The resulting displacement was measured and converted into strain. The applied force was divided by the cross-section area and converted into stress. The resulting strain vs. application voltage is plotted in FIG. 8, and the coefficients fitted to the data are tabulated in Table 2 to facilitate comparison. The outer diameter of sample B is 1.57 times larger than sample A, which predicts that sample A should produce the same strain with 1.57 times lower voltage. However, surprisingly, the observed electroactive coefficient (X in Table 2) shows that sample A produces the same strain as sample B but at 1.96 lower activation voltage. This 24% additional electroactivity is well explained by the fact that sample A has an alpha value of 2.06 vs. sample B that has an alpha value of 2.53.

TABLE 2
Quadratic Fit (X*V\hat{ }2 + Y*V + Z)

| | Sample A | Sample B | sqrt(Ratio) |
|---|---|---|---|
| X | 7.07E−06 | 1.85E−06 | 1.96 |
| Y | −1.72E−04 | 5.88E−05 | NA |
| Z | 7.87E−02 | 1.08E−03 | NA |

When ranges are used herein for physical properties, such as molecular weight, or chemical properties, such as chemical formulae, all combinations, and subcombinations of ranges for specific embodiments therein are intended to be included.

The disclosures of each patent, patent application, and publication cited or described in this document are hereby incorporated herein by reference, in its entirety.

Those skilled in the art will appreciate that numerous changes and modifications can be made to the preferred embodiments of the invention and that such changes and modifications can be made without departing from the spirit of the invention. It is, therefore, intended that the appended claims cover all such equivalent variations as fall within the true spirit and scope of the invention.

### REFERENCES

[1] R. Pelrine, Q. Pei, and R. Kornbluh, “Dielectric elastomers: past, present, and potential future,” 2018, vol. 10594, no., pp. 1059406-1059408.
[2] P. Brochu and Q. Pei, “Advances in dielectric elastomers for actuators and artificial muscles,” Macromolecular Rapid Communications, vol. 31, no. 1. pp. 10-36, 2010.
[3] Y. Bar-cohen and J. P. L. Caltech, “Artificial Muscles using Electroactive Polymers (EAP): Capabilities, Challenges and Potential Electroactive Polymers (EAP),” Robot. 2000, pp. 1-14, 2002.
[4] F. Carpi, D. De Rossi, R. Kornbluh, R. Pelrine, and P. Sommer-Larsen, Dielectric elastomers as electromechanical transducers: Fundamentals, Materials, Devices, Models and Applications of an Emerging Electroactive Polymer Technology. 2008.
[5] R. PELRINE, R. KORNBLUH, and G. KOFOD, “High-strain actuator materials based on dielectric elastomers,” Adv. Mater., vol. 12, no. 16, pp. 1223-1225, 2000.
[6] Y. Bar-Cohen, “Electroactive Polymer (EAP) Actuators as Artificial Muscles,” Yoseph Bar-Cohen, no. 1, p. 758, 2004.
[7] R. Pelrine, R. Kornbluh, and G. Kofod, “High-strain actuator materials based on dielectric elastomers,” Adv. Mater., vol. 12, no. 16, pp. 1223-1225, 2000.
[⁸] R. Kornbluh et al., “Electroelastomers: Applications of dielectric elastomer transducers for actuation, generation, and smart structures,” Proceeding SPIE Vol. 4698, vol. 4698, pp. 254-270, 2002.
[9] F. Carpi, C. Menon, and D. De Rossi, “Electroactive elastomeric actuator for all-polymer linear peristaltic pumps,” IEEE/ASME Trans. Mechatronics, vol. 15, no. 3, pp. 460-470, 2010.
[10] R. P. Heydt, R. Kornbluh, J. Eckerle, and R. Pelrine, “Dielectric elastomer loudspeakers,” in Dielectric Elastomers as Electromechanical Transducers, 2008, pp. 313-320.
[11] R. Pelrine et al., “Applications of dielectric elastomer actuators,” Proc. SPIE, vol. 4329, no. 1, pp. 335-349, 2001.
[12] L. Maffli, S. Rosset, M. Ghilardi, F. Carpi, and H. Shea, “Ultrafast all-polymer electrically tunable silicone lenses,” Adv. Funct. Mater., vol. 25, no. 11, pp. 1656-1665, 2015.
[13] I. A. Anderson et al., “A thin membrane artificial muscle rotary motor,” Appl. Phys. A Mater. Sci. Process., vol. 98, no. 1, pp. 75-83, 2010.
[14] B. M. O'Brien, T. G. McKay, T. A. Gisby, and I. A. Anderson, “Rotating turkeys and self-commutating artificial muscle motors,” Appl. Phys. Lett., vol. 100, no. 7, 2012.
[15] F. Carpi, A. Migliore, G. Serra, and D. De Rossi, “Helical dielectric elastomer actuators,” Smart Mater. Struct., vol. 14, no. 6, pp. 1210-1216, 2005.
[16] A. T. Conn and J. Rossiter, “Towards holonomic electro-elastomer actuators with six degrees of freedom,” Smart Mater. Struct., vol. 21, no. 3, 2012.
[17] R. Pelrine, “Dielectric elastomer artificial muscle actuators: toward biomimetic motion,” Proc. SPIE, vol. 4695, no. 3, pp. 126-137, 2002.
[18] G. Kovacs, L. During, S. Michel, and G. Terrasi, “Stacked dielectric elastomer actuator for tensile force transmission,” Sensors Actuators, A Phys., vol. 155, no. 2, pp. 299-307, 2009.
[19] C. T. Nguyen et al., “A small biomimetic quadruped robot driven by multistacked dielectric elastomer actuators,” Smart Mater. Struct., vol. 23, no. 6, 2014.
[20] Q. Pei, M. a. Rosenthal, R. Pelrine, S. Stanford, and R. D. Kornbluh, “Multifunctional electroelastomer roll actuators and their application for biomimetic walking robots,” SPIE Smart Struct. Mater., vol. 5051, pp. 281-290, 2003.
[21] R. Zhang, P. Lochmatter, G. Kovacs, A. Kunz, and F. Conti, “Portable force feedback device based on miniature rolled dielectric elastomer actuators,” in Dielectric Elastomers as Electromechanical Transducers, 2008, pp. 207-216.
[22] R. Alvarez Icaza Rivera, J. M. Alvarez Sanches, K. Galloway, H. Katzenberg, R. Kothari, and J. Arthur, “Dielectric elastomer fiber transducers,” US7834527, 2005.
[23] Hills Inc., “Hills Nano-Technology,” 2005.

What is claimed:

1. An electromechanically connected bundle of a plurality of dielectric elastomeric microfibers, comprising:
a. a direct mechanical connection between the cross-section annular face of each of the dielectric elastomeric microfibers and a supportive element (end cap); and
b. a direct electrical connection between the core of all microfibers and a conductive contact.

2. The electromechanically connected bundle of dielectric elastomeric microfibers of claim 1, wherein each of the direct mechanical and direct electrical connections are both achieved using an electrically conductive adhesive or electrically conductive bonding material.

3. The electromechanically connected bundle of dielectric elastomeric microfibers of claim 2, wherein the electrically conductive adhesive or electrically conductive bonding material physically bonds the conductive element to the microfiber wall material while being in electrical communication with the fluidic electrodes within the cores of the hollow dielectric elastomeric microfibers.

4. The electromechanically connected bundle of dielectric elastomeric microfibers of claim 3, wherein the electromechanically connected bundle of dielectric elastomeric microfibers is bonded with epoxy resin, cyanoacrylate or silicone.

5. The electromechanically connected bundle of dielectric elastomeric microfibers of claim 3, wherein the electromechanically connected bundle of dielectric elastomeric microfibers comprises a silicone.

6. The electromechanically connected bundle of dielectric elastomeric microfibers of claim 3, wherein the electrical connection is achieved by forming a fluidic cavity between the core of the microfibers and an electrically conductive contact, and wherein the mechanical connection is achieved at the periphery of the bundle's seal.

7. The electromechanically connected bundle of dielectric elastomeric microfibers of claim 1, wherein a conductive support has an array of pins or contacts inserted into the electrically conductive cores of each of the plurality of microfibers of the microfiber bundle.

8. The electromechanically connected bundle of dielectric elastomeric microfibers of claim 7, wherein the mechanical connection is strengthened by an adhesive or bonding agent.

9. The electromechanically connected bundle of dielectric elastomeric microfibers of claim 1, wherein the electrical connection is achieved by using a bonding pad ring and bonding wires similar to an integrated circuit.

10. The electromechanically connected bundle of dielectric elastomeric microfibers of claim 9, wherein the mechanical connection is achieved by an adhesive or bonding agent deposed on the face (cylindrical ring edge) or periphery of the bundle seal.

11. A DE microfiber, comprising: a hollow fiber body characterized as having an outer diameter and an inner diameter, an inner fluidic or compliant electrode deposed within the interior of the hollow fiber body, and an outer fluidic or compliant electrode deposed exterior to the hollow fiber body, wherein the ratio alpha of the outer diameter to the inner diameter of the hollow fiber body is chosen to maximize the electromechanical performance of the DE microfiber as an actuator.

12. The DE microfiber of claim 11, where the ratio alpha, is selected to maximize mechanical energy output.

13. The DE microfiber of claim 11, where the ratio alpha, is selected to maximize effective work density.

14. The DE microfiber of claim 11, where the ratio alpha, is selected to maximize effective specific energy.

15. The DE microfiber of claim 11, where the ratio alpha, is selected to maximize mechanical power density.

16. The DE microfiber of claim 11, where the ratio alpha, is selected to maximize mechanical specific power.

17. The DE microfiber of claim 11 where the ratio alpha is selected to maximize effective strain.

18. The DE microfiber of claim 11, where the ratio alpha, is selected to maximize effective_stress.

19. The DE microfiber of claim 11 where the electrical time-constant is lower than about 1000 ms, preferably lower than about 500 ms, and preferably lower than about 200 ms.

20. The DE microfiber of claim 11 where the OD is reduced to implement a failure rate of less than 1 in 1000 fibers within a bundle at the target operating voltage.

21. The DE microfiber of claim 11 where the resistivity of the inner electrode is engineered so that the fiber has an electrical time constant below about 200 ms.

22. The DE microfiber of claim 11 where the scale (OD), ratio alpha and resistivity of the inner electrode are selected so that the microfiber has an electrical time constant that matches the mechanical time constant of the application.

23. The DE microfiber of claim 11 where the hollow fiber body comprises a silicone elastomeric material.

24. The DE microfiber of claim 11 where the hollow fiber body comprises a thermoset elastomeric material.

25. The DE microfiber of claim 11 where the hollow fiber body comprises a thermoplastic elastomeric material.

26. The DE microfiber of claim 11 where the hollow fiber body comprises a urethane elastomeric material.

27. The DE microfiber of claim 11 where the hollow fiber body comprises a polyester elastomeric material.

28. The DE microfiber of claim 11 where the hollow fiber body comprises an acrylic elastomeric material.

29. The DE microfiber of claim 11 where the hollow fiber body comprises an elastomeric material characterized as having a Young's Modulus in the range of between 100 kPa and 5000 kPa.

30. The DE microfiber of claim 11 where the DE microfibers are characterized as having a passive elasticity constant between 400 kPa and 800 kPa.

31. The DE microfiber of claim 11 where the stress produced by the DE microfiber decreases to zero when electrically activated using an activation voltage between the inner and outer electrodes.

32. The DE microfiber of claim 11 where the DE microfiber is pre-stressed to produce a desired baseline stress when there is no activation voltage between the inner and outer electrodes.
